(19) United States
(12) Patent Application Publication
(10) Pub. No.: US 2024/0125858 A1
(43) Pub. Date: Apr. 18, 2024

(54) STATE OF CHARGE VALUE ESTIMATION METHOD FOR LITHIUM BATTERY

(71) Applicant: LIAN ZHENG ELECTRONICS (SHENZHEN) CO., LTD., SHENZHEN (CN)

(72) Inventors: YUBO WANG, Shenzhen (CN); YANMEI ZHAN, Shenzhen (CN); YAHONG XIE, Shenzhen (CN)

(21) Appl. No.: 18/477,786

(22) Filed: Sep. 29, 2023

(30) Foreign Application Priority Data
Oct. 11, 2022 (CN) 202211240447.7

(51) Int. Cl. G01R 31/367; G01R 31/378; G01R 31/388

(52) U.S. Cl. CPC G01R 31/367; G01R 31/378; G01R 31/388

(57) ABSTRACT

The present inventive concept provides a state of charge value estimation method for a lithium battery, including determining an estimated state of charge value by using an ampere-hour integral method; and when estimating that the lithium battery enters a low-current charging mode, determining a reference cell voltage value corresponding to the estimated state of charge value according to a look-up table, and comparing the reference cell voltage value and a measured real-time cell voltage value to determine a calibrated state of charge value. The state of charge value estimation method for a lithium battery of the present inventive concept is simple in operation and high in accuracy.

### CROSS-REFERENCE TO RELATED APPLICATIONS

Priority is claimed to Chinese Patent Application No. 202211240447.7 filed on Oct. 11, 2022, the entire disclosure of which is hereby incorporated by reference herein.

### TECHNICAL FIELD

The present inventive concept relates to the field of lithium batteries, and especially relates to a state of charge (SoC) value estimation method for a lithium battery, particularly to a state of charge value estimation method for a lithium battery used in an uninterruptible power supply (UPS).

### BACKGROUND

Due to the high energy density, long life, high discharge rate, and other properties of lithium batteries, more and more UPS products choose to use lithium batteries as energy storage. For the safety of lithium batteries and good expression of other performance, a corresponding battery management system (BMS) is very necessary, wherein the estimation of a SoC value is an important function of the BMS. SoC is the ratio of the capacity of a lithium battery to its capacity in a fully charged state, usually expressed as a percentage. Its value is in the range of 0% to 100%. When SoC=0, it indicates that the battery is fully discharged. When SoC=100%, it indicates that the battery is fully charged. At present, most SoC estimation methods used in the charging process of UPS products use an ampere-hour integral method, which is derived from the definition of battery capacity, specifically:

$$S o C ( t ) = S o {C}_{0} - \frac{1}{{c}_{r a t e d}} η \int I dt \qquad ( 1 )$$

where SoC(t) represents the current SoC value of a battery, SoC₀ represents an SoC value in an initial state (i.e., an initial SoC value), C_{rated} represents the rated capacity of the lithium battery, η represents the charging efficiency of the battery and ∫Idt represents an integral value of a charging current I with respect to time t.

### SUMMARY

The ampere-hour integral method is straightforward and simple and is easy to apply, and therefore is widely applied to lithium battery products. However, the accuracy of this method is particularly dependent on the accuracy of a current sampling circuit. In the UPS products, the maximum discharge current of the battery can reach 10 C or more, whereas the charging current is often only 0 C to 0.5 C, wherein C represents the battery charge and discharge capacity ratio, and 1 C indicates the current intensity when the battery is fully discharged in one hour. Therefore, the sampling range of the charging current of the lithium battery in the UPS products is only about one-tenth of the discharge current, thereby resulting in inaccurate sampling of the charging current. Especially when charging with a low current at a final stage, the charging current is too low, particularly less than the sensitivity of a current sampling circuit. The current sampling circuit often cannot collect the charging current at this stage, and cannot obtain accurate SoC values.

The UPS calculates an estimated backup time on the basis of the remaining battery capacity, and the remaining battery capacity Cᵣₑₘₐᵢₙ is based on the product of the rated capacity C_{rated} and SoC as set out in equation (2).

Cᵣₑₘₐᵢₙ=C_{rated}*SOC (2)

When the SoC value at the final stage of charging is inaccurate, the calculation in equation (2) may not accurately estimate the backup time, which will also cause troubles for users.

In addition, although the real-time SoC value can be measured in a laboratory environment, the relatively fixed laboratory data for fixed lithium batteries cannot be equivalent to the SoC data in the actual application environment of lithium batteries.

Therefore, the present inventive concept may overcome the above defects and provides a state of charge value estimation method for a lithium battery, comprising the following steps:
S1: determining an estimated state of charge value by using an ampere-hour integral method; and
S2: when estimating that the lithium battery enters a low-current charging mode, determining a reference cell voltage value corresponding to the estimated state of charge value according to a look-up table, and comparing the reference cell voltage value and a measured real-time cell voltage value so as to determine a calibrated state of charge value.

In the state of charge value estimation method for a lithium battery according to the present inventive concept, preferably, when the charging current is less than a predetermined threshold, it is estimated that the lithium battery enters the low-current charging mode.

In the state of charge value estimation method for a lithium battery according to the present inventive concept, preferably, when the estimated state of charge value is greater than a predetermined threshold, it is estimated that the lithium battery enters the low-current charging mode.

In the state of charge value estimation method for the lithium battery according to the present inventive concept, preferably, the ampere-hour integral method is based on the following formula:

$$S o C ( t ) = S o {C}_{0} - \frac{1}{{C}_{rated}} η \int Idt$$

wherein, SoC(t) represents the estimated state of charge value, SoC₀ represents an initial state of charge value, C_{rated} represents the rated capacity of the lithium battery, η represents the charging efficiency of the battery, and ∫Idt represents an integral value of a charging current I with respect to time t.

In the state of charge value estimation method for a lithium battery according to the present inventive concept, preferably, in step S1, the estimated state of charge value is determined by using a predetermined time period, wherein the estimated state of charge value determined in a previous time period is used as an initial state of charge value for a next time period.

In the state of charge value estimation method for a lithium battery according to the present inventive concept, preferably, the time period is determined according to the characteristics of the lithium battery.

In the state of charge value estimation method for a lithium battery according to the present inventive concept, preferably, determining the calibrated state of charge value includes:

when the measured real-time cell voltage value is greater than the reference cell voltage value, adding a step size value on the basis of the estimated state of charge value and using said step size value as the calibrated state of charge value; and

repeating steps S1 and S2 by using the calibrated SOC value as an initial SOC value.

In the state of charge value estimation method for a lithium battery according to the present inventive concept, preferably, when the calibrated state of charge value reaches 100%, it is determined that the lithium battery is fully charged.

In the state of charge value estimation method for a lithium battery according to the present inventive concept, preferably, the step size value is 0.01%, 0.1%, or 1%.

In the state of charge value estimation method for a lithium battery according to the present inventive concept, preferably, the look-up table is obtained by performing a charging test on the lithium battery in a laboratory environment.

In another aspect, the present inventive concept provides a computer-readable storage medium, wherein the computer-readable storage medium has a computer program stored thereon, and the computer program is executed to implement the state of charge value estimation method for a lithium battery according to the present inventive concept.

In yet another aspect, the present inventive concept provides an electronic device, comprising a processor and a memory, wherein the memory is used to store executable commands; and the processor is configured to implement the state of charge value estimation method for a lithium battery according to the present inventive concept by executing the executable commands.

The state of charge value estimation method for a lithium battery of the present inventive concept is simple to operate, and can provide an accurate state of charge value even in a low current mode, thereby improving user experience.

### BRIEF DESCRIPTION OF THE DRAWINGS

Embodiments of the present inventive concept are further described below with reference to the accompanying drawings:

FIG. 1 is charging current-cell voltage-SOC waveform diagrams obtained using a method known in the art.

FIG. 2 shows an SoC value-cell voltage relationship obtained from a laboratory environment test.

FIG. 3 is a flowchart of a state of charge value estimation method for a lithium battery according to an embodiment of the present inventive concept.

FIG. 4 is charging current-cell voltage-SOC waveform diagrams obtained using a method of the present inventive concept.

### DETAILED DESCRIPTION

In order to make the goal, technical solutions and advantages of the present inventive concept clearer, the present inventive concept will further be described in detail below through specific embodiments with reference to the drawings. It should be understood that the specific embodiments described herein are only intended to explain the present inventive concept, rather than to limit the present inventive concept.

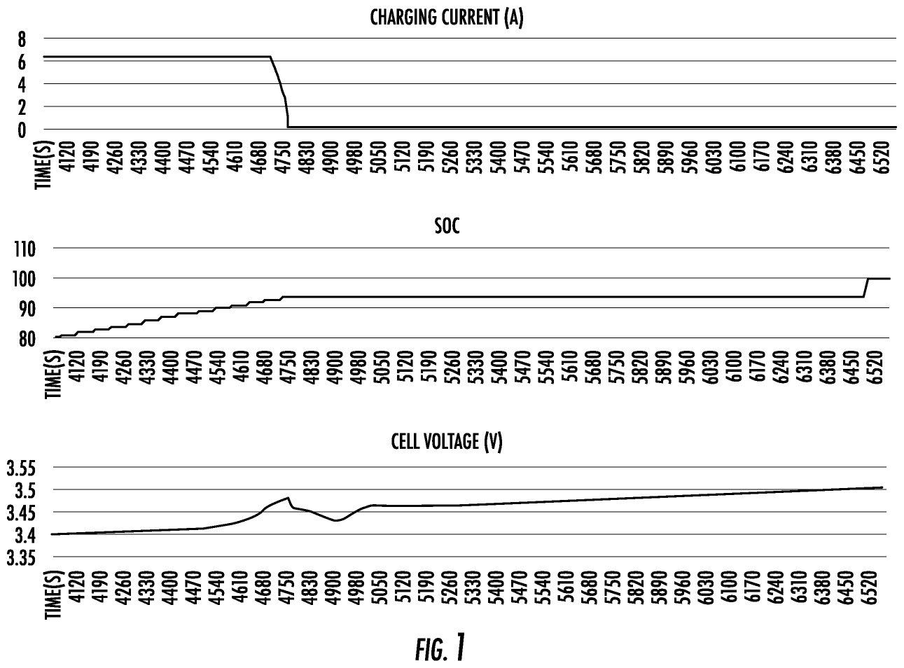

In accordance with the present inventive concept, changes in cell voltage during low-current charging have been analyzed. Taking the charging current-cell voltage-SOC waveform diagrams obtained using the known method shown in FIG. 1 as an example, when the cell voltage reaches 3.48 V, the BMS current limit turns to low-current charging. Since the charging current is too low, the BMS cannot sample the charging current at this time. The charging current is zero, and the SoC value remains unchanged until the cell voltage finally reaches 3.5 V to determine that the battery is fully charged, and SoC jumps directly from 94% to 100%. The error of the collected SoC data in the process of jumping from 94% to 100% is very large. However, in accordance with the present inventive concept, the present inventors found that the cell voltage continued to rise when charging with a low current. At the final stage of charging, although the charging current could no longer be sampled, the cell voltage value continued to increase with the low-current charging. The sampling accuracy of the cell voltage was high, and the error was within +/−10 mV. Therefore, the SoC value can be calibrated according to the cell voltage value at this time.

In a laboratory environment, a charging test is performed on the cell of the lithium battery multiple times, for example, using a commercially available high-precision charging test device, so as to simulate the conditions of the battery at the final stage of charging. Since both the cell voltage and the actual SoC value change with time during the charging process, there is a one-to-one correspondence between the two. The SoC value obtained by the ampere-hour integral method can be calibrated according to the cell voltage-SoC relationship obtained in the laboratory test. For example, under normal circumstances, when the SoC value of a lithium battery reaches a predetermined threshold (such as 80%) or more, the lithium battery enters a low-current charging state, and the ampere-hour integral method begins to have an error. In the laboratory environment, when the SoC value of the battery is greater than 80%, the actual SoC value and the corresponding cell voltage (herein, the cell voltage value is referred to as a “reference cell voltage”). As shown in Table 1, the SoC value and the corresponding reference cell voltage are used as a look-up table for a subsequent calibration process. The specific value of the reference cell voltage is not given here, because reference cell voltage values corresponding to the same SoC value are different for different lithium batteries and different cells. This table only reflects a one-to-one correspondence between the actual SoC value and the cell voltage.

TABLE 1

| SoC (%) | Reference cell voltage |
|---|---|
| 80 | V_80 |
| 81 | V_81 |
| 82 | V_82 |

. . .

| | |
|---|---|
| 98 | V_98 |
| 99 | V_99 |
| 100 | V_100 |

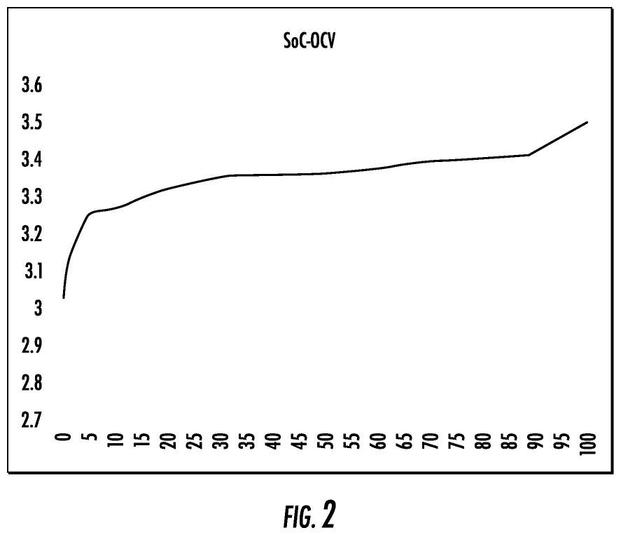

The SoC-OCV curve shown in FIG. 2 also shows the one-to-one correspondence between the SoC value and the cell voltage.

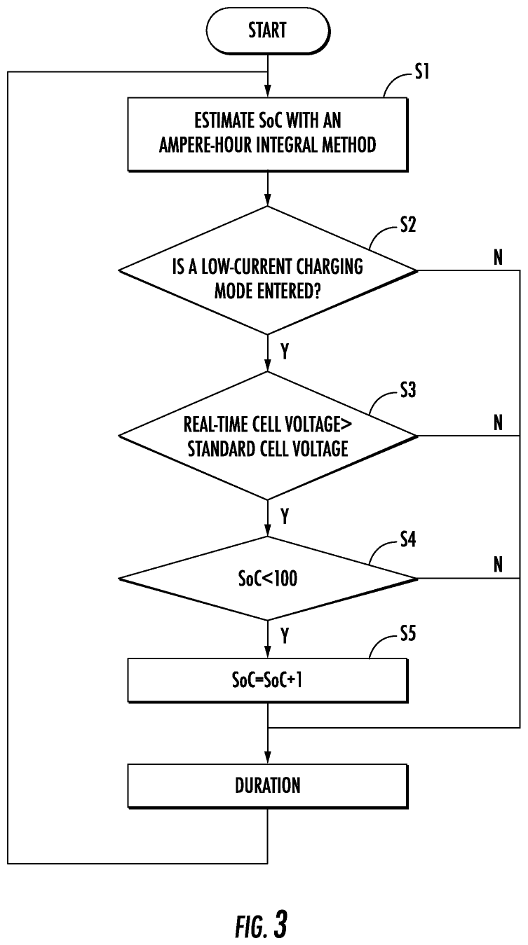

The SoC-OCV correspondence in Table 1 and FIG. 2 is applied in a low-current charging period at the final stage of battery charging and acts as a calibration method for estimating SoC by using the ampere-hour integral method at the final stage of charging, the calibration process thereof being shown in FIG. 3.
S1: Use an ampere-hour integral method to estimate an SoC value. Specifically, the aforementioned formula (1) is used to estimate an SoC value. Estimation is performed at a predetermined time period, that is, an output value of a previous time period is used as an initial value SoC₀ for a next time period and integral operation is performed. For different products, the time period is selected on the basis of the full charge time of a lithium battery, so the selected execution time period is different. For example, if a product can be fully charged in only 10 seconds, then its execution time period should be less than 100 milliseconds. If a product is fully charged in 100 minutes, then its execution time period should be less than 1 minute.
S2: Determine whether to enter a low-current charging mode, that is, compare the charging current with a threshold current; if the charging current is less than the threshold current, go to step S3; and if the charging current is greater than or equal to the threshold current, return to step S1 and continue to estimate with the ampere-hour integral method. The magnitude of the threshold current is also different for different products.
S3: Measure the current real-time cell voltage, compare the real-time cell voltage with a reference cell voltage corresponding to the current SoC value obtained from a lookup table; if the real-time cell voltage is greater than the reference cell voltage, then enter step S4; and if the real-time cell voltage is less than the reference cell voltage, return to step S1 and continue to estimate with the ampere-hour integral method.
S4: Determine whether the current SoC value is less than 100%; if so, go to step S5; and if not, return to step S1 and continue to estimate with the ampere-hour integral method.
S5: Perform SoC value calibration, add a step size value (such as 0.01%, 0.1%, or 1%) on the basis of the current SoC value to obtain an updated SoC value and output the same, continue for a period of time on the basis of the updated SoC value until the current execution time period ends, then return to step S1 and repeat the above loop, that is, use the updated SoC value as an initial value to estimate with the ampere-hour integral method, and repeat steps S1 to S5.

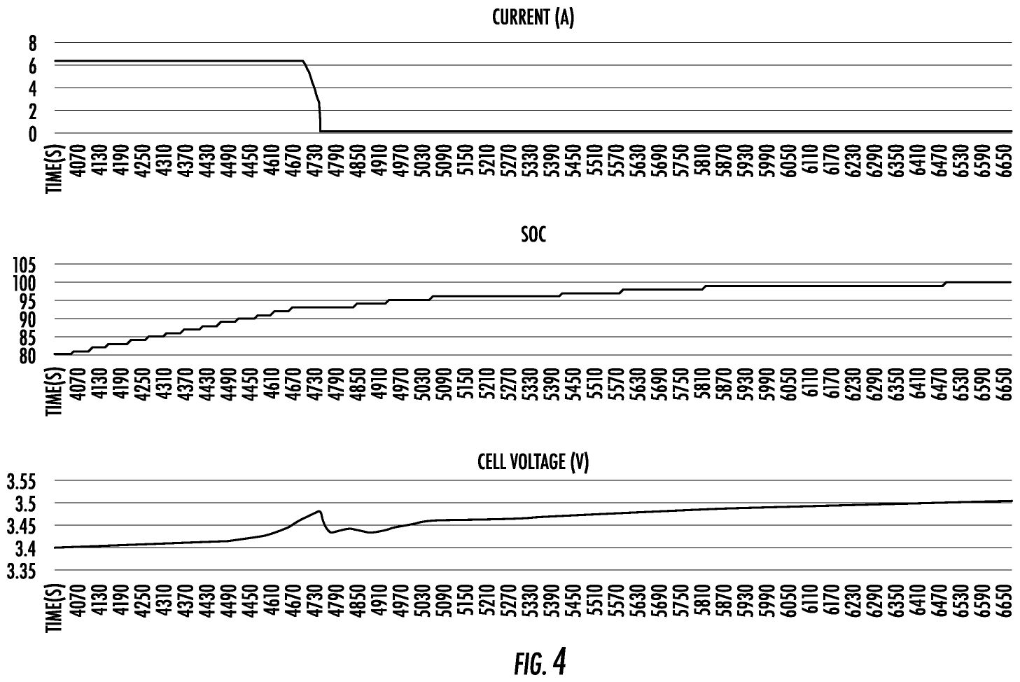

Referring to the charging current-cell voltage-SOC waveform diagrams obtained by the method of the present inventive concept shown in FIG. 4, after entering the low-current charging mode, the SoC value is calibrated by the cell voltage until the SoC value reaches 100%. It can be seen that the SoC curve collected by the method of the present inventive concept rises slowly, which eliminates SoC jumps in the low-current charging mode and is more accurate.

In general, in the SoC value estimation process of the present inventive concept, an ampere-hour integral method is first used for estimation, and when entering a low-current charging mode, an SoC value is calibrated on the basis of the comparison between the real-time cell voltage and a reference cell voltage. If the real-time cell voltage is greater than the reference cell voltage, a step size value (for example, 1) is added on the basis of the current SoC value, and then the calibrated SoC value is used as an initial value of a next execution time period for subsequent integral estimation and calibration. When the SoC value reaches 100%, estimation is stopped to obtain a complete SOC value curve.

Usually, when the SoC value of a lithium battery reaches a predetermined threshold or greater, a low-current charging state is entered. Therefore, in the SoC value estimation process, SoC value>SoC predetermined threshold may also be used as a judgment criterion for the low-current charging mode.

In another embodiment of the present inventive concept, there is further provided a computer-readable storage medium having a computer program or executable instructions stored thereon. When executed, the computer program or executable instructions implement the technical solutions as described in the preceding embodiments, the implementation principles of which are similar and are not redundantly described here. In the embodiments of the present inventive concept, the computer-readable storage medium may be any tangible medium capable of storing data and being read by a computing apparatus. Examples of computer-readable storage media include hard disk drives, network attached storage (NAS), read-only memories, random access memories, CD-ROM, CD-R, CD-RW, magnetic tapes, and other optical or non-optical data storage apparatuses. Computer-readable storage media may also include computer-readable media distributed on a network-coupled computer system, so that computer programs or instructions can be stored and executed in a distributed manner.

In yet another embodiment of the present inventive concept, there is further provided an electronic device, including a processor and a memory, wherein the memory is used to store executable instructions executable by the processor, and wherein the processor is configured to execute executable instructions stored on the memory, and the executable instructions, when executed, implement the technical solution described in any one of the preceding embodiments, the implementation principles of which are similar and are not redundantly described here.

Reference in the present description to “various embodiments,” “some embodiments,” “one embodiment,” “an embodiment” or the like refers to a particular feature, structure, or property described in connection with the embodiment being included in at least one embodiment. Therefore, appearances of the phrases “in various embodiments,” “in some embodiments,” “in one embodiment,” “in an embodiment” or the like in various places throughout the description are not necessarily referring to the same embodiment. Moreover, particular features, structures, or properties may be combined in any suitable manner in one or more embodiments. Therefore, particular features, structures, or properties shown or described in connection with one embodiment may be combined, in whole or in part, with features, structures, or properties of one or more other embodiments, as long as the combination is not non-logical or inoperable.

The terms “including” and “having”, as well as expressions having a similar meaning, in the present description are intended to cover non-exclusive inclusion. For example, processes, methods, systems, products, or devices including a series of steps or units are not limited to the listed steps or units, but optionally may further include a step or unit not listed, or optionally may further include other steps or units that are inherent to these processes, methods, products, or devices. “A” or “an” also does not exclude the plural form. In addition, the individual elements in the drawings of the present application are merely illustrative and are not drawn to scale.

Although the present inventive concept has been described through preferred embodiments, the present inventive concept is not limited to the embodiments described herein, but includes various changes and variations made without departing from the scope of the present inventive concept.

What is claimed is:

1. A state of charge value estimation method for a lithium battery, comprising:
S1: determining an estimated state of charge value by using an ampere-hour integral method; and
S2: when estimating that the lithium battery enters a low-current charging mode, determining a reference cell voltage value corresponding to the estimated state of charge value, and comparing the reference cell voltage value and a measured real-time cell voltage value to determine a calibrated state of charge value.

2. The state of charge value estimation method for a lithium battery according to claim 1, wherein when the charging current is less than a predetermined threshold, an estimation is made that the lithium battery enters the low-current charging mode.

3. The state of charge value estimation method for a lithium battery according to claim 1, wherein when the estimated state of charge value is greater than a predetermined threshold, an estimation is made that the lithium battery enters the low-current charging mode.

4. The state of charge value estimation method for a lithium battery according to claim 1, wherein the ampere-hour integral method is based on the following formula:
$$S o C ( t ) = S o {C}_{0} - \frac{1}{{C}_{rated}} η \int Idt$$
wherein, SoC(t) represents the estimated state of charge value, SoC₀ represents an initial state of charge value, C_{rated} represents the rated capacity of the lithium battery, represents the charging efficiency of the battery, and ∫Idt represents an integral value of a charging current I with respect to time t.

5. The state of charge value estimation method for a lithium battery according to claim 4, wherein, in S1, the estimated state of charge value is determined by using a predetermined time period, and the estimated state of charge value determined in a previous time period is used as an initial state of charge value for a next time period.

6. The state of charge value estimation method for a lithium battery according to claim 5, wherein the predetermined time period is determined according to characteristics of the lithium battery.

7. The state of charge value estimation method for a lithium battery according to claim 5, wherein determining the calibrated state of charge value comprises:
when the measured real-time cell voltage value is greater than the reference cell voltage value, adding a step size value based on the estimated state of charge value and using the step size value as the calibrated state of charge value; and
repeating S1 and S2 by using the calibrated SOC value as an initial SOC value.

8. The state of charge value estimation method for a lithium battery according to claim 7, wherein when the calibrated state of charge value reaches 100%, a determination is made that the lithium battery is fully charged.

9. The state of charge value estimation method for a lithium battery according to claim 7, wherein the step size value is 0.01%, 0.1%, or 1%.

10. The state of charge value estimation method for a lithium battery according to claim 1, further comprising a look-up table used to determine the reference cell voltage value corresponding to the estimated state of charge value, wherein the look-up table is obtained by performing a charging test on the lithium battery in a laboratory environment.

11. A computer-readable storage medium, wherein the computer-readable storage medium has a computer program stored thereon, and the computer program is executed to implement the state of charge value estimation method for a lithium battery according to claim 1.

12. An electronic device, comprising a processor and a memory, wherein the memory is used to store executable commands, and the processor is configured to implement the state of charge value estimation method for a lithium battery according to claim 1 by executing the executable commands.
